(19) United States
(12) Patent Application Publication
(10) Pub. No.: US 2026/0042978 A1
(43) Pub. Date: Feb. 12, 2026

(54) PROCESSING SOLUTION FOR SEMICONDUCTOR DEVICE

(71) Applicant: TOKYO OHKA KOGYO CO., LTD., Kanagawa (JP)

(72) Inventors: Takumi NAMIKI, Kanagawa (JP); Jun IIOKA, Kanagawa (JP); Kazuya TAJIMA, Kanagawa (JP)

(21) Appl. No.: 19/289,409

(22) Filed: Aug. 4, 2025

Related U.S. Application Data
(60) Provisional application No. 63/682,008, filed on Aug. 12, 2024.

(51) Int. Cl. C11D 7/32; C11D 7/08; C11D 7/26; H01L 21/02

(52) U.S. Cl. CPC C11D 7/3209; C11D 7/08; C11D 7/267; H01L 21/02068

(57) ABSTRACT

Provided is a processing solution for a semiconductor device, containing a fluorine-containing compound, a cyclic ether compound, a diaminoalkane, and water.

### CROSS-REFERENCE TO RELATED APPLICATIONS

The present application claims priority to U.S. Provisional application No. 63/682,008, filed with the United States Patent and Trademark Office on Aug. 12, 2024, the entire content of which is incorporated herein by reference.

### BACKGROUND OF THE INVENTION

### Technical Field

The present invention relates to a processing solution for a semiconductor device.

### Description of the Related Art

In a process of manufacturing a semiconductor device such as a semiconductor element, a dry etching process is usually employed when a semiconductor integrated circuit is formed. In the dry etching process, dry etching residues such as fluorine-based residues are generated, and it is necessary to remove the dry etching residues. Further, the semiconductor device to be processed may use a metal material for wiring (for example, cobalt, tungsten, and the like).

As an example of such a processing solution, Patent Document 1 (WO 2018/61582 A1) describes a processing solution for a semiconductor device that contains a fluorine-containing compound and a water-soluble aromatic compound having a benzene ring without having a heterocyclic group, and has a pH of 5 or less.

### PATENT LITERATURE

Patent Document 1: WO 2018/61582 A1

### SUMMARY OF THE INVENTION

There are various metal materials for wiring used in semiconductor devices and masking materials used in dry etching, and combinations thereof are also various. Therefore, development of a novel processing solution for a semiconductor device is required from the viewpoint of an anticorrosion effect on various metal materials used for wiring of a semiconductor device and the like. Examples of such a semiconductor device may include a substrate having a layer containing cobalt atoms (cobalt atom-containing layer) or a layer containing a tungsten atom (tungsten atom-containing layer). In this regard, excellent anticorrosion properties for the cobalt atom-containing layer and the tungsten atom-containing layer, as well as excellent removability of dry etching residues such as fluorine-based residues, are required; however, there is still room for improvement.

The present invention has been made in view of such circumstances, and an object of the present invention is to provide a processing solution for a semiconductor device having excellent anticorrosion properties for a cobalt atom-containing layer and a tungsten atom-containing layer and having excellent removability of fluorine-based residues.

As a result of intensive studies to achieve the above-described object, the present inventors have found that it is effective to use a processing solution for a semiconductor device, containing a fluorine-containing compound, a cyclic ether compound, a diaminoalkane, and water, thereby completing the present invention.

That is, the present invention is as follows.

<1>

A processing solution for a semiconductor device, containing: a fluorine-containing compound; a cyclic ether compound; a diaminoalkane; and water.

<2>

The processing solution for a semiconductor device according to <1>, wherein the fluorine-containing compound is at least one selected from the group consisting of hydrogen fluoride, ammonium fluoride, tetrafluoroboric acid, tetramethylammonium fluoride, and triethanolamine hydrofluoride.

<3>

The processing solution for a semiconductor device according to <1>, wherein, in the cyclic ether compound, the number of carbon atoms forming a ring is 2 to 4, and the number of oxygen atoms forming a ring is 1 to 2.

<4>

The processing solution for a semiconductor device according to <1>, wherein a content of the cyclic ether compound is 0.000001 mass % to 0.01 mass %.

<5>

The processing solution for a semiconductor device according to <1>, wherein the diaminoalkane is a compound represented by the following Formula (1):

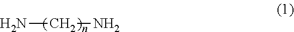

wherein n represents a number of 1 to 15.
   <6>

The processing solution for a semiconductor device according to <1>, wherein the semiconductor device includes a substrate having a metal layer containing a cobalt atom, and the processing solution for a semiconductor device is used for processing the metal layer.

<7>

The processing solution for a semiconductor device according to <1>, wherein the semiconductor device includes a substrate having a metal layer containing a tungsten atom, and the processing solution for a semiconductor device is used for processing the metal layer.

<8>

The processing solution for a semiconductor device according to <1>, wherein the processing solution for a semiconductor device is used for removing residues generated after an etching process is performed on the substrate having a metal layer, the substrate being used for manufacturing the semiconductor device.

According to the present invention, it is possible to provide a processing solution for a semiconductor device having excellent anticorrosion properties for a cobalt atom-containing layer and a tungsten atom-containing layer and having excellent removability of fluorine-based residues.

### DETAILED DESCRIPTION

Hereinafter, modes for carrying out the present invention (hereinafter, simply referred to as “the present embodiment”) will be described in detail. The following present embodiment is an example for describing the present invention, and is not intended to limit the present invention to the following contents. The present invention can be appropriately modified and implemented within the scope of the gist thereof. In addition, the configurations and parameters disclosed in the present specification can be any combination unless otherwise specified. Furthermore, an upper limit and a lower limit of the values disclosed in the present specification can be any combination unless otherwise specified.

### <Processing Solution for Semiconductor Device>

A processing solution for a semiconductor device according to the present embodiment (hereinafter, simply referred to as “processing solution”) is a processing solution for a semiconductor device, containing a fluorine-containing compound, a cyclic ether compound, a diaminoalkane, and water. In a conventional processing solution, it has been attempted to add an acid component such as hydrogen fluoride to the processing solution to improve residue removability; however, in this case, anticorrosion properties tend to deteriorate, and there is room for improvement in achieving both the residue removability and the anticorrosion properties at a practical level. For example, since cobalt and tungsten are promising semiconductor materials not only at present but also for the next generation, an increase in demand for a processing process of such a substrate is expected. In the development of a cleaning solution for the purpose of removing residues after dry etching in a semiconductor manufacturing process, corrosiveness (damage) to tungsten in a cleaning solution containing a fluorine-containing compound such as hydrogen fluoride cannot be ignored, and use thereof is restricted.

In this regard, the processing solution according to the present embodiment has unexpectedly excellent anticorrosion properties for the cobalt atom-containing layer and the tungsten atom-containing layer, as well as excellent removability of the fluorine-based residues, and thus can be suitably used as a processing solution for a semiconductor device having a cobalt atom-containing layer and/or a tungsten atom-containing layer. Although the reason for this is not clear, it is presumed that a processing solution that uses a combination of a fluorine-containing compound, a cyclic ether compound, and a diaminoalkane can protect cobalt and tungsten from corrosion while maintaining residues (however, the effects of the present embodiment are not limited thereto). Hereinafter, each component will be described.

### ((a) Fluorine-Containing Compound)

The processing solution according to the present embodiment contains a fluorine-containing compound. Specific examples of the fluorine-containing compound (a) may include, but are not particularly limited to, hydrogen fluoride, ammonium fluoride, tetrafluoroboric acid, ammonium tetrafluoroborate, tetramethylammonium fluoride, and triethanolamine hydrofluoride. Note that these also include isomers such as ammonium bifluoride and tetraalkylammonium bifluoride. In particular, the fluorine-containing compound is preferably at least one selected from the group consisting of hydrogen fluoride, ammonium fluoride, tetrafluoroboric acid, tetramethylammonium fluoride, and triethanolamine hydrofluoride, more preferably hydrogen fluoride and/or ammonium fluoride, and still more preferably hydrogen fluoride. Note that these fluorine-containing compounds may be salts. In addition, the fluorine-containing compound is preferably a compound that does not contain metal ions. These fluorine-containing compounds may be used alone or in combination with two or more kinds thereof. By using such a fluorine-containing compound, both the anticorrosion properties for the cobalt atom-containing layer and the tungsten atom-containing layer and the removability of the fluorine-based residues can be achieved at a higher level.

A content of the fluorine-containing compound is not particularly limited, and is preferably 0.01 to 10 mass %. A lower limit of the content of the fluorine-containing compound is more preferably 0.03 mass % or more, still more preferably 0.05 mass % or more, even more preferably 0.07 mass % or more, and yet more preferably 0.1 mass % or more. In addition, an upper limit of the content of the fluorine-containing compound is more preferably 5 mass % or less, still more preferably 3 mass % or less, even more preferably 1 mass % or less, and yet more preferably 0.5 mass % or less. By setting the content of the fluorine-containing compound within the above range, both the anticorrosion properties for the cobalt atom-containing layer and the tungsten atom-containing layer and the removability of the fluorine-based residues can be achieved at a higher level.

Note that the content of each component in the processing solution for a semiconductor device may be adjusted to the concentration in advance, or may be provided as a concentrated product in a distribution and supply mode and then diluted to the concentration when used for processing an electronic device.

### ((b) Cyclic Ether Compound)

The processing solution according to the present embodiment contains a cyclic ether compound. The cyclic ether compound (b) preferably contains one ring containing an oxygen atom in the molecule. The number of carbon atoms forming a ring in the cyclic ether compound is preferably 2 to 4. The number of carbon atoms forming a ring referred to herein is the number of carbon atoms forming one ring. In addition, the number of oxygen atoms forming a ring of the cyclic ether compound is preferably 1 to 2.

A molecular weight of the cyclic ether compound is not particularly limited, and is preferably 200 or less, more preferably 150 or less, still more preferably 105 or less, even more preferably 90 or less, and yet more preferably 50 or less. In addition, a lower limit of the molecular weight of the cyclic ether compound is preferably 40 or more.

Specific examples of the cyclic ether compound may include ethylene oxide (oxirane; molecular weight: 44.5), 1,4-dioxane (molecular weight: 88.1), tetrahydrofuran (THF; molecular weight 72.1), and 4-methyltetrahydropyran (MTHP; molecular weight: 100). Among them, ethylene oxide (EO) and 1,4-dioxane (DO) are preferable, and ethylene oxide is more preferable. These cyclic ether compounds may be used alone or in combination with two or more kinds thereof. By using such a cyclic ether compound, both the anticorrosion properties for the cobalt atom-containing layer and the tungsten atom-containing layer and the removability of the fluorine-based residues can be achieved at a higher level.

Note that the cyclic ether compound preferably contains ethylene oxide and 1,4-dioxane, and more preferably contains only ethylene oxide and/or 1,4-dioxane. When ethylene oxide and 1,4-dioxane are used in combination, a mass ratio (ethylene oxide:1,4-dioxane) is, for example, preferably 10:90 to 90:10, more preferably 15:85 to 85:15, still more preferably 30:70 to 70:30, and even more preferably 40:60 to 60:40.

A content of the cyclic ether compound is preferably 0.000001 mass % to 0.01 mass %. A lower limit of the content of the cyclic ether compound is more preferably 0.000005 mass % or more, still more preferably 0.000008 mass % or more, and still more preferably 0.00001 mass % or more. In addition, an upper limit of the content of the cyclic ether compound is more preferably 0.005 mass % or less, still more preferably 0.003 mass % or less, even more preferably 0.001 mass % or less, yet more preferably 0.0001 mass % or less, and even yet more preferably 0.00007 mass % or less. Note that, when two or more kinds of cyclic ether compounds are used in combination, the total content of the respective components is preferably within the above numerical range. By setting the content of the cyclic ether compound within the above range, both the anticorrosion properties for the cobalt atom-containing layer and the tungsten atom-containing layer and the removability of the fluorine-based residues can be achieved at a higher level.

### ((c) Diaminoalkane)

The processing solution according to the present embodiment contains a diaminoalkane. The structure of the diaminoalkane (c) is not particularly limited, and may be linear or branched, but is preferably linear. Furthermore, the diaminoalkane preferably has a linear alkylene group (—(CH₂)ₙ—, wherein n represents a number). The number of carbon atoms in the diaminoalkane is not particularly limited, and is preferably 1 to 15. A lower limit of the number of carbon atoms in the diaminoalkane is more preferably 3 or more, still more preferably 4 or more, even more preferably 5 or more, and yet more preferably 6 or more. In addition, an upper limit of the number of carbon atoms in the diaminoalkane is more preferably 13 or less, still more preferably 12 or less, even more preferably 11 or less, and yet more preferably 10 or less. By using such a diaminoalkane, both the anticorrosion properties for the cobalt atom-containing layer and the tungsten atom-containing layer and the removability of the fluorine-based residues can be achieved at a higher level.

The diaminoalkane is preferably a compound represented by the following Formula (1).

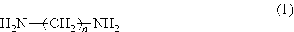

In the formula, n represents a number of 1 to 15.

In Formula (1), n is 1 to 15, and a lower limit of n is more preferably 3 or more, still more preferably 4 or more, even more preferably 5 or more, and yet more preferably 6 or more. In addition, an upper limit of n is more preferably 13 or less, still more preferably 12 or less, even more preferably 11 or less, and yet more preferably 10 or less. By setting the number of carbon atoms within such a numerical range, both the anticorrosion properties for the cobalt atom-containing layer and the tungsten atom-containing layer and the removability of the fluorine-based residues can be achieved at a higher level.

As a specific example of the diaminoalkane, at least one selected from the group consisting of 1,6-diaminohexane, 1,7-diaminoheptane, 1,8-diaminooctane, and 1,10-diaminodecane is preferable. Note that diaminoalkanes may be used alone or in combination with two or more kinds thereof.

A content of the diaminoalkane is preferably 50 ppm by mass to 3,000 ppm by mass. A lower limit of the content of the diaminoalkane is more preferably 60 ppm by mass or more, still more preferably 70 ppm by mass or more, and even more preferably 80 ppm by mass or more. In addition, an upper limit of the content of the diaminoalkane is more preferably 2,500 ppm by mass or less, still more preferably 2,000 ppm by mass or less, even more preferably 1,500 ppm by mass or less, and yet more preferably 1,300 ppm by mass or less. Note that “ppm” is on a mass basis (ppm by mass) unless otherwise specified. In addition, when two or more kinds of diaminoalkanes are used in combination, the total content of the respective components is preferably within the above numerical range. By setting the content of the diaminoalkane within the above range, both the anticorrosion properties for the cobalt atom-containing layer and the tungsten atom-containing layer and the removability of the fluorine-based residues can be achieved at a higher level.

### ((d) Water)

The processing solution according to the present embodiment contains water. In the present embodiment, water is not particularly limited, and it is preferable that metal ions, organic impurities, particles, and the like are removed or reduced by distillation, ion exchange treatment, filter treatment, various adsorption treatments, and the like. As the water, for example, pure water, ultrapure water, deionized water, and the like are preferable.

A content of water is not particularly limited, but it is used as a solvent. The solvents may be used in combination with an organic solvent described below. Water may be contained as the balance of the above-described components and components described below, and is usually 40 to 99.999 mass % with respect to the total amount of the processing solution for a semiconductor device. A lower limit of the content of water may be, for example, 80 mass % or more, 90 mass % or more, or 95 mass % or more. An upper limit of the content of water may be, for example, 99.998 mass % or less or 99.99 mass % or less.

### ((e) Organic Solvent)

The processing solution according to the present embodiment may further contain an organic solvent. As the organic solvent (e), for example, a water-soluble organic solvent can be used. The organic solvent (e) may be any organic solvent that is miscible with the above-described components (a), (b), (c), and (d), and an appropriate organic solvent can be selected in consideration of the kinds and contents of other components to be used. Note that the organic solvent is preferably an organic solvent other than the compounds corresponding to the component (a), the component (b), and the component (c). In addition, when the organic solvent (e) is used, the organic solvent (e) is preferably a water-soluble organic solvent other than the above-described cyclic ether compound (b).

Specific examples of the water-soluble organic solvent may include alcohols such as isopropanol, ethanol, ethylene glycol, propylene glycol, glycerin, 1,3-propanediol, 1,3-butanediol, 1,4-butanediol, diethylene glycol, dipropylene glycol, furfuryl alcohol, and 2-methyl-2,4-pentanediol; ethers such as ethylene glycol monomethyl ether, ethylene glycol monoethyl ether, ethylene glycol monobutyl ether, diethylene glycol monomethyl ether, diethylene glycol monoethyl ether, and diethylene glycol monobutyl ether; acetates such as ethylene glycol monomethyl ether acetate and ethylene glycol monoethyl ether acetate; sulfoxides such as dimethyl sulfoxide (DMSO); sulfones such as dimethylsulfone, diethylsulfone, bis(2-hydroxyethyl)sulfone, and tetramethylene sulfone; amides such as N,N-dimethylformamide (DMF), N-methylformamide, N,N-dimethylacetamide, N-methylacetamide, and N,N-diethylacetamide; lactams such as N-methyl-2-pyrrolidone (NMP), N-ethyl-2-pyrrolidone, N-propyl-2-pyrrolidone, N-hydroxymethyl-2-pyrrolidone, and N-hydroxyethyl-2-pyrrolidone; imidazolidinones such as 1,3-dimethyl-2-imidazolidinone, 1,3-diethyl-2-imidazolidinone, and 1,3-diisopropyl-2-imidazolidinone; and lactones such as γ-butyrolactone and 8-valerolactone. These water-soluble organic solvents may be used alone or in combination with two or more kinds thereof.

A content of the organic solvent with respect to the total of the content of water and the content of the organic solvent is preferably 40 mass % or less, more preferably 30 mass % or less, still more preferably 20 mass % or less, and even more preferably 10 mass % or less. In addition, a lower limit of the content of the organic solvent with respect to the total of the content of water and the content of the organic solvent is not particularly limited, and may be 0.01 mass % or more or 0.1 mass % or more.

Note that the processing solution according to the present embodiment is preferably a water-based processing solution (also sometimes referred to as an aqueous processing solution or the like) from the viewpoint of solubility of the components, environmental load reduction, economic efficiency, and the like. The water-based processing solution is a processing solution that does not contain an organic solvent, or a processing solution containing water and an organic solvent in which a content of the organic solvent is lower than a content of water. From such a viewpoint, as a more preferred aspect, the content of the organic solvent in the processing solution according to the present embodiment is preferably 20 mass % or less, more preferably 10 mass % or less, still more preferably 5 mass % or less, even more preferably 3 mass % or less, and yet more preferably 0 mass % or less (that is, only water is contained as a solvent).

### ((f) Other Components)

The processing solution according to the present embodiment may further contain optional components other than the above-described components as long as the effects of the present embodiment can be obtained. As such optional components, a suitable component can be appropriately selected in consideration of the composition of the processing solution, the purpose of use, and the material and configuration of the semiconductor device or the like to be processed. Examples of the optional components may include an anticorrosive agent, a surfactant, a pH adjuster, and a buffer.

### (Anticorrosive Agent)

The processing solution for a semiconductor device according to the present embodiment may contain an anticorrosive agent. Examples of the anticorrosive agent may include compounds containing nitrogen-containing heterocyclic rings such as a triazole ring, an imidazole ring, a pyridine ring, a phenanthroline ring, a tetrazole ring, a pyrazole ring, a pyrimidine ring, and a purine ring.

Examples of the compound containing a triazole ring may include triazoles such as 1,2,3-triazole, 1,2,4-triazole, 3-amino-1H-1,2,4-triazole, 1-acetyl-1H-1,2,3-triazolo[4,5-b]pyridine, 1H-1,2,3-triazolo[4,5-b]pyridine, 1,2,4-triazolo[4,3-a]pyridin-3(2H)-one, and 3H-1,2,3-triazolo[4,5-b]pyridin-3-ol; and benzotriazoles such as 1,2,3-benzotriazole, 5-methyl-1H-benzotriazole, 1-hydroxybenzotriazole, 1-hydroxypropylbenzotriazole, 2,3-dicarboxypropylbenzotriazole, 4-hydroxybenzotriazole, 4-carboxyl-1H-benzotriazole, 4-carboxyl-1H-benzotriazole methyl ester, 4-carboxyl-1H-benzotriazole butyl ester, 4-carboxyl-1H-benzotriazole octyl ester, 5-hexylbenzotriazole, [1,2,3-benzotriazolyl-1-methyl][1,2,4-triazolyl-1-methyl][2-ethylhexyl]amine, tolyltriazole, naphthotriazole, bis[(1-benzotriazolyl)methyl]phosphonic acid, and 3-aminotriazole.

Examples of the compound containing an imidazole ring may include imidazoles such as 2-methylimidazole, 2-ethylimidazole, 2-isopropylimidazole, 2-propylimidazole, 2-butylimidazole, 4-methylimidazole, 2,4-dimethylimidazole, 2-ethyl-4-methylimidazole, 2-undecylimidazole, 2-aminoimidazole, and benzimidazole; and biimidazoles such as 2,2′-biimidazole.

Examples of the compound containing a pyridine ring may include pyridines such as 1H-1,2,3-triazolo[4,5-b]pyridine, 1-acetyl-1H-1,2,3-triazolo[4,5-b]pyridine, 3-aminopyridine, 4-aminopyridine, 3-hydroxypyridine, 4-hydroxypyridine, 2-acetamidopyridine, 4-pyrrolidinopyridine, 2-cyanopyridine, 2,6-pyridinecarboxylic acid, and 2,4,6-trimethylpyridine; and bipyridyls such as 2,2′-bipyridyl, 4,4′-dimethyl-2,2′-bipyridyl, 4,4′-di-tert-butyl-2,2′-bipyridyl, 4,4′-dinonyl-2,2′-bipyridyl, 2,2″-bipyridine-6,6′-dicarboxylic acid, and 4,4′-dimethoxy-2,2′-bipyridyl.

Examples of the compound containing a phenanthroline ring may include 1,10-phenanthroline.

Examples of the compound containing a tetrazole ring may include 1H-tetrazole, 5-amino-1H-tetrazole, 5-methyl-1H-tetrazole, 5-phenyl-1H-tetrazole, and 1-(2-diaminoethyl)-5-mercaptotetrazole.

Examples of the compound containing a pyrazole ring may include 3,5-dimethylpyrazole, 3-amino-5-methylpyrazole, 4-methylpyrazole, and 3-amino-5-hydroxypyrazole.

Examples of the compound containing a pyrimidine ring may include pyrimidine, 4-methylpyrimidine, 1,2,4-triazolo[1,5-a]pyrimidine, 1,3,4,6,7,8-hexahydro-2H-pyrimido[1,2-a]pyrimidine, 1,3-diphenyl-pyrimidine-2,4,6-trione, 1,4,5,6-tetrahydropyrimidine, 2,4,5,6-tetraaminopyrimidine sulfate, 2,4,5-trihydroxypyrimidine, 2,4,6-triaminopyrimidine, 2,4,6-trichloropyrimidine, 2,4,6-trimethoxypyrimidine, 2,4,6-triphenylpyrimidine, 2,4-diamino-6-hydroxypyrimidine, 2,4-diaminopyrimidine, 2-acetamidopyrimidine, 2-aminopyrimidine, 2-methyl-5,7-diphenyl-(1,2,4)triazolo(1,5-a)pyrimidine, 2-methylsulfanyl-5,7-diphenyl-(1,2,4)triazolo(1,5-a)pyrimidine, 2-methylsulfanyl-5,7-diphenyl-4,7-dihydro-(1,2,4)triazolo(1,5-a)pyrimidine, and 4-aminopyrazolo[3,4-d]pyrimidine.

Examples of the compound containing a purine ring may include adenine, guanine, hypoxanthine, xanthine, uric acid, and theophylline.

The anticorrosive agents may be used alone or in combination with two or more kinds thereof.

When the processing solution for a semiconductor device according to the present embodiment contains an anticorrosive agent, a content of the anticorrosive agent is not particularly limited, and is preferably 0.0001 to 1.0 mass % (1 to 10,000 ppm by mass) with respect to the total mass of the processing solution for a semiconductor device.

The processing solution for a semiconductor device according to the present embodiment may not contain one or more selected from the group consisting of a compound containing a triazole ring, a compound containing an imidazole ring, a compound containing a pyridine ring, a compound containing a phenanthroline ring, a compound containing a tetrazole ring, a compound containing a pyrazole ring, a compound containing a pyrimidine ring, and a compound containing a purine ring, and may not contain one or more of the above-described compounds exemplified as specific examples of the anticorrosive agent. The processing solution for a semiconductor device according to the present embodiment may not contain an anticorrosive agent.

### (Surfactant)

The processing solution for a semiconductor device according to the present embodiment may contain a surfactant for preventing foaming and adjusting wettability of the cleaning solution to the substrate. Examples of the surfactant may include a nonionic surfactant, an anionic surfactant, a cationic surfactant, and an amphoteric surfactant.

Examples of the nonionic surfactant may include a polyalkylene oxide alkyl phenyl ether-based surfactant, a polyalkylene oxide alkyl ether-based surfactant, a block polymer-based surfactant composed of polyethylene oxide and polypropylene oxide, a polyoxyalkylene distyrenated phenyl ether-based surfactant, a polyalkylene tribenzyl phenyl ether-based surfactant, and an acetylene polyalkylene oxide-based surfactant.

Examples of the anionic surfactant may include alkyl sulfonic acid, alkyl benzene sulfonic acid, alkyl naphthalene sulfonic acid, alkyl diphenyl ether sulfonic acid, fatty acid amide sulfonic acid, polyoxyethylene alkyl ether carboxylic acid, polyoxyethylene alkyl ether acetic acid, polyoxyethylene alkyl ether propionic acid, alkyl phosphonic acid, and salts of fatty acids.

Examples of the “salts” may include ammonium salts, sodium salts, potassium salts, and tetramethylammonium salts.

Examples of the cationic surfactant may include an alkylpyridinium-based surfactant.

Examples of the amphoteric surfactant may include a betaine-based surfactant, an amino acid-based surfactant, an imidazoline-based surfactant, and an amine oxide-based surfactant.

These surfactants are generally commercially available. The surfactants may be used alone or in combination with two or more kinds thereof.

When the processing solution for a semiconductor device according to the present embodiment contains a surfactant, a content of the surfactant is not particularly limited, and is preferably 0.0001 to 5 mass % with respect to the total mass of the processing solution for a semiconductor device. When the content of the surfactant is within such a range, bubbles generated by a foaming agent tend to be dense.

The processing solution for a semiconductor device according to the present embodiment may not contain one or more selected from the group consisting of a nonionic surfactant, an anionic surfactant, a cationic surfactant, and an amphoteric surfactant, and may not contain one or more of the compounds exemplified as these surfactants. The processing solution for a semiconductor device according to the present embodiment may not contain a surfactant.

### (pH Adjuster)

The processing solution for a semiconductor device according to the present embodiment may contain a pH adjuster. Examples of the pH adjuster may include an acidic compound and a basic compound. The basic compound may be an organic basic compound or an inorganic basic compound. The processing solution for a semiconductor device according to the present embodiment may not contain a pH adjuster.

### (Buffer)

The processing solution for a semiconductor device according to the present embodiment may contain a buffer. The buffer is a compound having a function of suppressing a change in pH of the processing solution for a semiconductor device. As the buffer, a compound having pH buffering ability can be appropriately used.

The buffers may be used alone or in combination with two or more kinds thereof. When the processing solution for a semiconductor device according to the present embodiment contains a buffer, a content of the buffer is not particularly limited, and is preferably 0.001 to 10 mass % with respect to the total mass of the processing solution for a semiconductor device.

The processing solution for a semiconductor device according to the present embodiment may not contain a buffer.

### (Impurities and the Like)

The processing solution for a semiconductor device according to the present embodiment may contain, for example, metal impurities including metal atoms such as Fe atoms, Cr atoms, Ni atoms, Zn atoms, Ca atoms, and Pb atoms. The total content of the metal atoms in the processing solution for a semiconductor device according to the present embodiment is preferably 100 ppt by mass or less with respect to the total mass of the processing solution for a semiconductor device. A lower limit of the total content of the metal atoms is preferably as low as possible, and is, for example, 0.001 ppt by mass or more. The total content of the metal atoms is, for example, 0.001 ppt by mass to 100 ppt by mass. By setting the total content of the metal atoms to be equal to or less than the above-described preferred upper limit, defect suppressing property and residue suppressing property of the cleaning solution are improved. It is considered that when the total content of the metal atoms is set to be equal to or more than the above-described preferred lower limit, the metal atoms hardly exist in the system separately, and the manufacturing yield of the entire target to be cleaned is hardly adversely affected.

A content of the metal impurities can be adjusted, for example, by a purification process such as filtering. The purification process such as filtering may be performed on a part or all of the raw materials before preparing the cleaning solution or may be performed after the processing solution for a semiconductor device is prepared.

The processing solution for a semiconductor device according to the present embodiment may contain, for example, impurities derived from organic substances (organic impurities). The total content of the organic impurities in the processing solution for a semiconductor device according to the present embodiment is preferably 5,000 ppm by mass or less. A lower limit of the content of the organic impurities is preferably as low as possible, and is, for example, 1 ppq by mass or more. Examples of the total content of the organic impurities may include 1 ppq by mass to 5,000 ppm by mass.

The processing solution for a semiconductor device according to the present embodiment may contain, for example, targets to be counted having a size countable by a light scattering type in-liquid particle counter. The size of the target to be counted is, for example, 0.04 m or more. The number of the targets to be counted in the processing solution for a semiconductor device according to the present embodiment per 1 mL of the processing solution for a semiconductor device is, for example, 1,000 or less, and a lower limit of the number of the targets to be counted is, for example, 0.1 or more. It is considered that, when the number of targets to be counted in the processing solution for a semiconductor device is within the above-described range, the effect of preventing metal corrosion, the effect of reducing defects, and the like by the processing solution for a semiconductor device are improved (however, the effects of the present embodiment are not limited thereto).

The size of the target to be counted may be a size detectable by a light scattering type in-liquid particle counter and may be, for example, 0.001 μm or more.

The above-described organic impurities and/or the targets to be counted may be added to the cleaning solution or may be inevitably mixed into the cleaning solution in a manufacturing process of the processing solution for a semiconductor device. Examples of cases where the organic impurities are inevitably mixed in the manufacturing process of the processing solution for a semiconductor device may include, but are not limited to, a case where the organic impurities are included in a raw material (for example, an organic solvent) used for manufacturing the processing solution for a semiconductor device, and a case where the organic impurities are mixed from an external environment in the manufacturing process of the processing solution for a semiconductor device (for example, contamination).

When the targets to be counted are added to the processing solution for a semiconductor device, an abundance ratio may be adjusted for each specific size considering surface roughness and the like of the object to be cleaned.

(pH)

A pH of the processing solution for a semiconductor device according to the present embodiment is not particularly limited, and is preferably 1 to 8. A lower limit of the pH is more preferably 2 or more, and still more preferably 3 or more. In addition, an upper limit of the pH is more preferably 7 or less, and still more preferably 6 or less. By setting the pH within such a range, it is possible to more easily achieve both anticorrosion properties and cleaning performance.

### <Method for Storing Processing Solution for Semiconductor Device and the Like>

A method for storing the processing solution according to the present embodiment is not particularly limited, and a conventionally known storage container can also be used. In order to ensure the stability of the processing solution, the void ratio in the container when storing the processing solution and/or the type of gas used to fill the void space may be appropriately set. For example, the void ratio in the storage container is about 0.01 to 30 vol %.

The processing solution according to the present embodiment may be stored as a highly-concentrated chemical solution before use (hereinafter, sometimes referred to as “concentrated chemical solution”), and when used, the concentrated chemical solution may be diluted 2-fold to 2,000-fold to prepare a processing solution having the above-described desired content, which may be used for processing a semiconductor device. As a diluting solvent for the concentrated chemical solution, water can be used, for example. In this regard, the above-described water-based processing solution is also preferable in that such concentration and dilution can be easily performed. Note that, during concentration and dilution, a purification process may be appropriately performed as necessary. As the purification method, a known method can be used depending on the kind and content of the component.

### <Method for Using Processing Solution for Semiconductor Device, Method for Processing Semiconductor Device, and the Like>

The processing solution for a semiconductor device according to the present embodiment has at least excellent anticorrosion properties for the cobalt atom-containing layer and the tungsten atom-containing layer and excellent removability of the fluorine-based residues, and thus can be suitably used as a processing solution for processing a substrate having a cobalt atom-containing layer and/or a tungsten atom-containing layer. The configuration of the substrate to be processed is not particularly limited, but an example is shown below.

Examples of a configuration of a multilayer substrate of the semiconductor device may include a multilayer substrate in which functional layers such as metal wiring, a metal layer, an etching stop layer, an insulating layer, and an interlayer insulating film (ILD), and a protective film (hard mask layer, HM layer) are laminated on a substrate.

Examples of the material of the substrate may include substrate materials such as silicon, amorphous silicon, polysilicon, and glass.

Examples of metals used for the metal wiring or metal layer may include at least one selected from the group consisting of metals such as cobalt (Co), tungsten (W), molybdenum (Mo), ruthenium (Ru), copper (Cu), iron (Fe), nickel (Ni), silicon (Si), aluminum (Al), lead (Pb), zinc (Zn), tin (Sn), tantalum (Ta), magnesium (Mg), bismuth (Bi), cadmium (Cd), zirconium (Zr), antimony (Sb), manganese (Mn), beryllium (Be), chromium (Cr), germanium (Ge), vanadium (V), gallium (Ga), hafnium (Hf), indium (In), niobium (Nb), rhenium (Re), and thallium (Ti), and metal oxides, metal nitrides, metal chlorides, and metal fluorides thereof. From the viewpoint of effectively utilizing the advantages of the present embodiment, cobalt and/or tungsten is preferably contained. These may be a cobalt alloy or a tungsten alloy. In addition, for example, in the case of a silicon-based material, SiN, SiO₂, a Low-k film (a SiOC film, a SiCOH film, or the like), an ILD, and the like are exemplified.

Examples of the material of the etching stop layer may include aluminum oxide, SiN, SiON, and SiOCN.

Examples of the material of the interlayer insulating film (ILD) may include silicon-based materials such as SiO₂, SiN, SiOC, and SiOCN. The interlayer insulating film can be used, for example, as a functional layer that insulates wiring between multilayer wirings having a plurality of layers.

The material of the protective film (hard mask layer, HM layer) may be any material as long as it functions as a protective film against etching, the material is not particularly limited, and a suitable material can be appropriately selected in consideration of manufacturing conditions and the like. Examples of the material of the protective film may include silicon-based materials such as SiN, SiO₂, SiON, and SiCN, titanium-based materials such as Ti and TiN, and combinations thereof.

Then, the processing method using the processing solution for an electronic device according to the present embodiment includes a step of bringing the above-described processing solution for a semiconductor device into contact with an electronic device (a substrate or the like). For example, etching residues can be removed by bringing the processing solution for a semiconductor device into contact with an electronic device (for example, a semiconductor element) in the etching step (or steps before and after the etching step). Furthermore, removal of a protective film such as a hard mask layer can also be expected. Note that the etching method is not particularly limited, and may be wet etching or dry etching, but is preferably dry etching. In the case of dry etching, it is advantageous from the viewpoint that metal wiring at a nano level is possible and gas to be used can be controlled. In addition, in the case of dry etching, there is a concern that damage to the substrate and the like is relatively large, but it is also desirable that the advantages of the present embodiment can be more effectively reflected from the viewpoint that such damage can be effectively suppressed by using the processing solution according to the present embodiment.

As a method for bringing the processing solution into contact with an electronic device (a substrate or the like), for example, the processing solution is stored in a container, and the electronic device to be cleaned is immersed in the processing solution to remove dry etching residues, such that the electronic device can be processed. Alternatively, by processing the electronic device by a single-wafer cleaning method, it is possible to remove dry etching residues and process the electronic device. The processing solution is suitably used not only as a dry etching residue removal solution (cleaning solution) but also as an etching solution. In addition, the processing solution according to the present embodiment can also be used as a cleaning solution for cleaning the electronic device after the step of chemical mechanical polishing (CMP). Then, before and after the processing step using the processing solution, a rinsing step using an organic solvent, water, carbonated water, ammonia water, or the like may be performed.

As a processing temperature using the processing solution for a semiconductor device, a suitable processing temperature can be appropriately selected in consideration of the configuration of the semiconductor device to be processed, the composition of the processing solution, and the like. The processing temperature is usually 10 to 80° C. A lower limit of the processing temperature is more preferably 15° C. or higher and still more preferably 20° C. or higher. In addition, an upper limit of the processing temperature is preferably 70° C. or lower, more preferably 65° C. or lower, still more preferably 60° C. or lower, and even more preferably 50° C. or lower.

As a processing time using the processing solution for a semiconductor device, a suitable processing time can be appropriately selected in consideration of the configuration of the semiconductor device to be processed, the composition of the processing solution, and the like. The processing time is usually 10 seconds to 60 minutes.

As described above, the processing solution according to the present embodiment can be used as, for example, a processing solution for removing residues generated in a semiconductor etching step or the like. In particular, the processing solution according to the present embodiment can suppress damage to various metal layers such as a cobalt atom-containing layer and a tungsten atom-containing layer, and can effectively remove residues generated by dry etching such as fluorine-based residues. From such a viewpoint, in the processing solution according to the present embodiment, it is preferable that the semiconductor device includes a substrate having a metal layer containing a cobalt atom, and the processing solution for a semiconductor device is a processing solution for a semiconductor device used for processing the metal layer. Alternatively, in the processing solution according to the present embodiment, it is preferable that the semiconductor device includes a substrate having a metal layer containing a tungsten atom, and the processing solution for a semiconductor device is a processing solution for a semiconductor device used for processing the metal layer. In addition, the processing solution according to the present embodiment is preferably a processing solution for a semiconductor device used for removing residues generated after an etching process is performed on the substrate having a metal layer, the substrate being used for manufacturing the semiconductor device.

### EXAMPLES

Hereinafter, the present invention will be described in more detail with reference to examples, but the present invention is not limited by these examples.

### (Preparation of Processing Solutions for Semiconductor Device)

Processing solutions for a semiconductor device (processing solutions) were prepared by mixing the respective components so as to have the compositions shown in Tables 1 to 3. Note that water was used as the balance in preparing each processing solution. Note that the components used in the present examples described in the tables are as follows.
HF: hydrogen fluoride
1,6-Diaminohexane
1,7-Diaminoheptane
1,8-Diaminooctane
1,10-Diaminodecane
Octylamine
8-Amino-1-octanol
12-Amino-1-dodecanol
7-Aminoheptanoic acid
Dipropylamine
2-Methyl-1,5-diaminopentane
1,3-Diaminopentane
1,2-Cyclohexanediamine
Bis(hexamethylene)triamine
Tetraethylenepentamine
Triethylenetetramine
Diethylenetriamine
EO: Ethylene oxide (ethylene oxide, 3-membered ring, 2 carbon atoms, 1 oxygen atom)
DO: 1,4-Dioxane (6-membered ring, 4 carbon atoms, 2 oxygen atoms)
Mixture of EO and DO: mixed solvent in which ethylene oxide and 1,4-dioxane are mixed at a mass ratio of 1:1 (EO:DO=1:1, mass ratio)

### (Evaluation of Anticorrosion Properties for Cobalt)

A cobalt film was prepared as a model film, and the etchability was evaluated based on the etching amount. The thickness of the model film was 150 Å. Then, an etching treatment of the model film was performed using the processing solutions of each example and each comparative example. As conditions of the etching treatment, the model film was immersed in a processing solution (25° C.) for 15 minutes, rinsed with ultrapure water (25° C.) for 3 seconds, then washed with isopropyl alcohol (25° C.) for 30 seconds, and dried by nitrogen blow. Then, the etchability was determined based on the film thickness difference of the model film before and after immersion in the processing solution.

Note that the film thickness of the model film before and after the treatment was measured by X-ray fluorescence analysis using “ZSX Primus IV” (manufactured by Rigaku Corporation). The etching amount (film loss) was determined and evaluated according to the following criteria.
A: The film loss was less than 10 Å.
B: The film loss was 10 Å or more and less than 20 Å.
C: The film loss was 20 Å or more.

### (Evaluation of Anticorrosion Properties for Tungsten)

A tungsten film was prepared as a model film, and the etchability was evaluated based on the etching amount. The thickness of the model film was 80 Å. Then, an etching treatment of the model film was performed using the processing solutions of each example and each comparative example. As conditions of the etching treatment, the model film was immersed in a processing solution (25° C.) for 30 minutes, rinsed with ultrapure water (25° C.) for 3 seconds, then washed with isopropyl alcohol (25° C.) for 30 seconds, and dried by nitrogen blow. Then, the etchability was determined based on the film thickness difference of the model film before and after immersion in the processing solution.

Note that the film thickness of the model film before and after the treatment was measured by X-ray fluorescence analysis using “ZSX Primus IV” (manufactured by Rigaku Corporation). The etching amount (film loss) was determined and evaluated according to the following criteria.

A: The film loss was less than 10 Å.

B: The film loss was 10 Å or more and less than 50 Å.

C: The film loss was 50 Å or more.

### (Evaluation of Residue Removability of Fluorine-Based Residues)

Evaluation was performed using a TiN substrate after a dry etching treatment using a fluorine-based gas. First, the processing solutions of each example and each comparative example were placed in beakers. Then, the TiN substrate was immersed in the processing solution at 25° C. for 3 minutes, rinsed with ultrapure water (25° C.) for 3 seconds, then washed with isopropyl alcohol (25° C.) for 30 seconds, and dried by nitrogen blow. Thereafter, the residual amount of fluorine-based residues on the TiN substrate was measured by X-ray photoelectron spectroscopy (XPS) using an X-ray photoelectron spectrometer “K-ALPHA+” (manufactured by Thermo Fisher Scientific Inc.).

Note that the residual amount of fluorine-based residues was determined by using Comparative Example 1 as a control, with the amount of residual fluorine defined as 100% (reference value), and determining the degree of variation from that value. Specifically, the evaluation was performed and determined according to the following criteria.

A: The residual amount of fluorine-based residues was equivalent to the residual amount of fluorine-based residues in the control (100%) (within a range of 100±5%) or less than that amount (less than 105%).

B: The residual amount of fluorine-based residues exceeded the residual amount of fluorine-based residues in the control (100%) (a value higher than 105%).

The compositions of each example and each comparative example are shown in Tables 1 to 3, and the evaluation results of each example and each comparative example are shown in Tables 4 and 5.

TABLE 1

| | Fluorine- | | | | | | |
|---|---|---|---|---|---|---|---|
| | containing | | | | Cyclic ether | | |
| | compound | Content | Diaminoalkane | Content | compound | Content | Water |
| Comparative | HF | 0.2 wt % | None | None | None | None | Balance |
| Example 1 | | | | | | | |
| Comparative | HF | 0.2 wt % | None | None | EO | 0.00001 wt % | Balance |
| Example 2 | | | | | | | |
| Example 1 | HF | 0.2 wt % | 1,6- | 100 ppm | EO | 0.00001 wt % | Balance |
| | | | Diaminohexane | | | | |
| Example 2 | HF | 0.2 wt % | 1,6- | 300 ppm | EO | 0.00001 wt % | Balance |
| | | | Diaminohexane | | | | |
| Example 3 | HF | 0.2 wt % | 1,6- | 400 ppm | EO | 0.00001 wt % | Balance |
| | | | Diaminohexane | | | | |
| Example 4 | HF | 0.2 wt % | 1,6- | 500 ppm | EO | 0.00001 wt % | Balance |
| | | | Diaminohexane | | | | |
| Example 5 | HF | 0.2 wt % | 1,6- | 600 ppm | EO | 0.00001 wt % | Balance |
| | | | Diaminohexane | | | | |
| Example 6 | HF | 0.2 wt % | 1,6- | 700 ppm | EO | 0.00001 wt % | Balance |
| | | | Diaminohexane | | | | |
| Example 7 | HF | 0.2 wt % | 1,6- | 1000 ppm | EO | 0.00001 wt % | Balance |
| | | | Diaminohexane | | | | |
| Example 8 | HF | 0.2 wt % | 1,6- | 1000 ppm | EO | 0.00005 wt % | Balance |
| | | | Diaminohexane | | | | |
| Example 9 | HF | 0.2 wt % | 1,6- | 1000 ppm | DO | 0.00005 wt % | Balance |
| | | | Diaminohexane | | | | |
| Example 10 | HF | 0.2 wt % | 1,6- | 1000 ppm | Mixture of | 0.00005 wt % | Balance |
| | | | Diaminohexane | | EO and DO | | |
| Comparative | HF | 0.2 wt % | 1,6- | 1000 ppm | Mixture of | 0.00005 wt % | Balance |
| Example 3 | | | Diaminohexane | | EO and DO | | |
| Comparative | HF | 0.2 wt % | 1,6- | 1000 ppm | None | None | Balance |
| Example 4 | | | Diaminohexane | | | | |

TABLE 2

| | Fluorine- | | | | | | |
|---|---|---|---|---|---|---|---|
| | containing | | | | Cyclic ether | | |
| | compound | Content | Diaminoalkane | Content | compound | Content | Water |
| Example 11 | HF | 0.2 wt % | 1,7- | 100 ppm | EO | 0.00001 wt % | Balance |
| | | | Diaminoheptane | | | | |
| Example 12 | HF | 0.2 wt % | 1,7- | 300 ppm | EO | 0.00001 wt % | Balance |
| | | | Diaminoheptane | | | | |
| Example 13 | HF | 0.2 wt % | 1,7- | 500 ppm | EO | 0.00001 wt % | Balance |
| | | | Diaminoheptane | | | | |
| Example 14 | HF | 0.2 wt % | 1,7 | 700 ppm | EO | 0.00001 wt % | Balance |
| | | | Diaminoheptane | | | | |
| Example 15 | HF | 0.2 wt % | 1,7- | 1000 ppm | EO | 0.00001 wt % | Balance |
| | | | Diaminoheptane | | | | |
| Comparative | HF | 0.2 wt % | 1,7- | 1000 ppm | None | None | Balance |
| Example 5 | | | Diaminoheptane | | | | |
| Example 16 | HF | 0.2 wt % | 1,8- | 400 ppm | EO | 0.00001 wt % | Balance |
| | | | Diaminooctane | | | | |
| Example 17 | HF | 0.2 wt % | 1,8- | 600 ppm | EO | 0.00001 wt % | Balance |
| | | | Diaminooctane | | | | |
| Example 18 | HF | 0.2 wt % | 1,8- | 800 ppm | EO | 0.00001 wt % | Balance |
| | | | Diaminooctane | | | | |
| Example 19 | HF | 0.2 wt % | 1,8- | 1000 ppm | EO | 0.00001 wt % | Balance |
| | | | Diaminooctane | | | | |
| Example 20 | HF | 0.2 wt % | 1,8- | 1000 ppm | EO | 0.00005 wt % | Balance |
| | | | Diaminooctane | | | | |
| Example 21 | HF | 0.2 wt % | 1,8- | 1000 ppm | DO | 0.00005 wt % | Balance |
| | | | Diaminooctane | | | | |
| Example 22 | HF | 0.2 wt % | 1,8- | 1000 ppm | Mixture of | 0.00005 wt % | Balance |
| | | | Diaminooctane | | EO and DO | | |
| Comparative | HF | 0.2 wt % | 1,8- | 1000 ppm | None | None | Balance |
| Example 6 | | | Diaminooctane | | | | |
| Example 23 | HF | 0.2 wt % | 1,10- | 1000 ppm | EO | 0.00001 wt % | Balance |
| | | | Diaminodecane | | | | |

TABLE 3

| | Fluorine- | | | | | | |
|---|---|---|---|---|---|---|---|
| | containing | | | | Cyclic ether | | |
| | compound | Content | Diaminoalkane | Content | compound | Content | Water |
| Comparative | HF | 0.2 wt % | Octylamine | 500 ppm | EO | 0.00001 wt % | Balance |
| Example 7 | | | | | | | |
| Comparative | HF | 0.2 wt % | Octylamine | 750 ppm | EO | 0.00001 wt % | Balance |
| Example 8 | | | | | | | |
| Comparative | HF | 0.2 wt % | Octylamine | 1000 ppm | EO | 0.00001 wt % | Balance |
| Example 9 | | | | | | | |
| Comparative | HF | 0.2 wt % | 8-Amino-1-Octanol | 1000 ppm | EO | 0.00001 wt % | Balance |
| Example 10 | | | | | | | |
| Comparative | HF | 0.2 wt % | 12-Amino-1-Dodecanol | 1000 ppm | EO | 0.00001 wt % | Balance |
| Example 11 | | | | | | | |
| Comparative | HF | 0.2 wt % | 7-Aminoheptanoic acid | 1000 ppm | EO | 0.00001 wt % | Balance |
| Example 12 | | | | | | | |
| Comparative | HF | 0.2 wt % | Dipropylamine | 1000 ppm | EO | 0.00001 wt % | Balance |
| Example 13 | | | | | | | |
| Comparative | HF | 0.2 wt % | 2-Methyl-1,5- | 1000 ppm | EO | 0.00001 wt % | Balance |
| Example 14 | | | diaminopentane | | | | |
| Comparative | HF | 0.2 wt % | 1,3-Diaminopentane | 1000 ppm | EO | 0.00001 wt % | Balance |
| Example 15 | | | | | | | |
| Comparative | HF | 0.2 wt % | 1,2- | 1000 ppm | EO | 0.00001 wt % | Balance |
| Example 16 | | | Cyclohexanediamine | | | | |
| Comparative | HF | 0.2 wt % | Bis (hexamethylene) | 1000 ppm | EO | 0.00001 wt % | Balance |
| Example 17 | | | triamine | | | | |
| Comparative | HF | 0.2 wt % | Tetraethylenepentamine | 1000 ppm | EO | 0.00001 wt % | Balance |
| Example 18 | | | | | | | |
| Comparative | HF | 0.2 wt % | Triethylenetetramine | 1000 ppm | EO | 0.00001 wt % | Balance |
| Example 19 | | | | | | | |
| Comparative | HF | 0.2 wt % | Diethylenetriamine | 1000 ppm | EO | 0.00001 wt % | Balance |
| Example 20 | | | | | | | |

TABLE 4

| | Co anticorrosion | W anticorrosion | Residue |
|---|---|---|---|
| | properties | properties | removal |
| Comparative Example 1 | C | C | Control |
| Comparative Example 2 | A | C | A |
| Example 1 | A | B | A |
| Example 2 | A | B | A |
| Example 3 | A | B | A |
| Example 4 | A | B | A |
| Example 5 | A | B | A |
| Example 6 | A | B | A |
| Example 7 | A | B | A |
| Example 8 | A | B | A |
| Example 9 | A | B | A |
| Example 10 | A | B | A |
| Comparative Example 3 | C | B | A |
| Comparative Example 4 | C | B | A |
| Example 11 | A | B | A |
| Example 12 | A | B | A |
| Example 13 | A | B | A |
| Example 14 | A | B | A |
| Example 15 | A | B | A |
| Comparative Example 5 | C | B | A |

TABLE 5

| | Co anticorrosion | W anticorrosion | Residue |
|---|---|---|---|
| | properties | properties | removal |
| Example 16 | A | A | A |
| Example 17 | A | A | A |
| Example 18 | A | A | A |
| Example 19 | A | A | A |
| Example 20 | A | A | A |
| Example 21 | A | A | A |
| Example 22 | A | A | A |
| Comparative Example 6 | C | A | A |
| Example 23 | A | A | B |
| Comparative Example 7 | A | A | B |
| Comparative Example 8 | A | A | B |
| Comparative Example 9 | A | A | B |
| Comparative Example 10 | A | C | A |
| Comparative Example 11 | A | A | B |
| Comparative Example 12 | A | C | A |
| Comparative Example 13 | A | C | A |
| Comparative Example 14 | A | B | B |
| Comparative Example 15 | A | B | B |
| Comparative Example 16 | A | B | B |
| Comparative Example 17 | A | B | B |
| Comparative Example 18 | A | B | B |
| Comparative Example 19 | A | B | B |
| Comparative Example 20 | A | B | B |

From the above, it can be at least confirmed that the processing solution for a semiconductor device according to the present embodiment has excellent anticorrosion properties for a cobalt atom-containing layer and a tungsten atom-containing layer and has excellent removability of fluorine-based residues.

What is claimed is:

1. A processing solution for a semiconductor device, comprising:
a fluorine-containing compound;
a cyclic ether compound;
a diaminoalkane; and
water.

2. The processing solution for a semiconductor device according to claim 1, wherein
the fluorine-containing compound is at least one selected from the group consisting of hydrogen fluoride, ammonium fluoride, tetrafluoroboric acid, tetramethylammonium fluoride, and triethanolamine hydrofluoride.

3. The processing solution for a semiconductor device according to claim 1, wherein,
in the cyclic ether compound, the number of carbon atoms forming a ring is 2 to 4, and the number of oxygen atoms forming a ring is 1 to 2.

4. The processing solution for a semiconductor device according to claim 1, wherein
a content of the cyclic ether compound is 0.000001 mass % to 0.01 mass %.

5. The processing solution for a semiconductor device according to claim 1, wherein
the diaminoalkane is a compound represented by the following Formula (1): 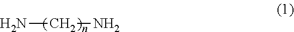
wherein n represents a number of 1 to 15.

6. The processing solution for a semiconductor device according to claim 1, wherein
the semiconductor device comprises a substrate having a metal layer containing a cobalt atom, and
the processing solution for a semiconductor device is used for processing the metal layer.

7. The processing solution for a semiconductor device according to claim 1, wherein
the semiconductor device comprises a substrate having a metal layer containing a tungsten atom, and
the processing solution for a semiconductor device is used for processing the metal layer.

8. The processing solution for a semiconductor device according to claim 1, wherein
the processing solution for a semiconductor device is used for removing residues generated after an etching process is performed on the substrate having a metal layer, the substrate being used for manufacturing the semiconductor device.
